(19) United States
(12) Patent Application Publication
(10) Pub. No.: US 2025/0031297 A1
(43) Pub. Date: Jan. 23, 2025

(54) CIRCUIT BOARD AND IMAGE FORMING APPARATUS

(71) Applicant: CANON KABUSHIKI KAISHA, Tokyo (JP)

(72) Inventor: TORU MIYAZAWA, Chiba (JP)

(21) Appl. No.: 18/769,818

(22) Filed: Jul. 11, 2024

(30) Foreign Application Priority Data
Jul. 20, 2023 (JP) 2023-118422

(51) Int. Cl. H05K 1/02; G03G 15/00; H05K 1/18; H05K 7/20

(52) U.S. Cl. CPC H05K 1/0203; G03G 15/80; H05K 1/181; H05K 7/20136; H05K 2201/10189; H05K 2201/10545

(57) ABSTRACT

A circuit board includes a first mounting area to which a first electronic part having at least a first function is mountable, and a second mounting area to which a second electronic part having higher heat dissipation than the first electronic part and at least the first function is mountable, wherein the first mounting area is provided on a first mounting surface of the circuit board, wherein the second mounting area is provided on a second mounting surface of the circuit board, the second mounting surface being different from the first mounting surface, and wherein heat dissipation of the first mounting surface is higher than heat dissipation of the second mounting surface.

### BACKGROUND OF THE INVENTION

### Field of the Invention

The present disclosure relates to a circuit board on which electronic parts are mounted, and to a printer, a copying machine, or a multifunction peripheral, including such a circuit board.

### Description of the Related Art

An image forming apparatus includes a plurality of circuit boards for control of a plurality of constituent part for use in forming an image. The circuit boards for control include a circuit board having a function of performing image processing control, and a circuit board having a function of sheet conveyance control. For each of the circuit boards for control, according to a function to be embodied, a plurality of electronic parts including an electronic part for performing a logic operation, an electronic part for performing a drive control, and an electronic part for generating a power supply voltage and the like are mounted. The electronic part on the circuit board is connected by a conductor wire such as a printed wiring line. Each electronic part forms, together with its surrounding electronic part, an electronic part component for implementing a predetermined function. For example, an integrated circuit, surrounding electronic parts such as a resistor, a capacitor, and an inductor, which are connected to input/output terminals of the integrated circuit, form the electronic part component.

The image forming apparatus prints an image on a sheet through a plurality of steps such as sheet conveyance, image formation, image transfer onto a sheet, and fixing of an image to the sheet. Accordingly, the image forming apparatus is required to control a wide variety of actuators, such as an optical sensor, a temperature sensor, a motor, and a solenoid. On the circuit board for control to be installed on the image forming apparatus, a plurality of electronic parts for controlling the actuators are mounted. For example, a driver board for driving a motor includes, in order to control the motor appropriately, an integrated circuit (motor driver IC) for generating a motor drive signal based on a control signal input from a controller (Japanese Patent Application Laid-open No. 2022-006639). Further, the circuit board for control itself is also provided as a plurality of circuit boards for control in the image forming apparatus.

### SUMMARY OF THE INVENTION

A circuit board according to one embodiment of the present disclosure includes a first mounting area to which a first electronic part having at least a first function is mountable, and a second mounting area to which a second electronic part having higher heat dissipation than the first electronic part and at least the first function is mountable, wherein the first mounting area is provided on a first mounting surface of the circuit board, wherein the second mounting area is provided on a second mounting surface of the circuit board, the second mounting surface being different from the first mounting surface, and wherein heat dissipation of the first mounting surface is higher than heat dissipation of the second mounting surface.

Further features of the present invention will become apparent from the following description of exemplary embodiments (with reference to the attached drawings).

### BRIEF DESCRIPTION OF THE DRAWINGS

FIG. 1 is a system configuration diagram of an image forming apparatus.

FIG. 2 is a configuration diagram of the image forming apparatus.

FIG. 3 is a configuration diagram of a circuit board.

FIG. 4 is an explanatory diagram of electronic part components.

FIG. 5 is a configuration diagram of the circuit board at the time of mounting motor driver ICs.

FIG. 6 is a configuration diagram of the circuit board at the time of mounting the motor driver ICs.

FIG. 7 is an explanatory diagram of motor drive IC temperature.

### DESCRIPTION OF THE EMBODIMENTS

In a case where mounting areas for electronic parts are provided on both sides of a board, it is desirable to consider heat dissipation from both sides of the board. In a case where the electronic parts are mounted exclusively on a circuit board having front and back surfaces, the electronic part mounted on a surface with low heat dissipation tend to be at higher risk of operational failures such as thermal shutdown and failure occurrence. Methods to suppress temperature rise include increasing the number of circuit board layers and placing additional fans. However, these methods lead to increased complexity and increased cost for an apparatus.

Now, a description is given of at least one exemplary embodiment of the present disclosure with reference to the accompanying drawings.

### Configuration of Image Forming Apparatus

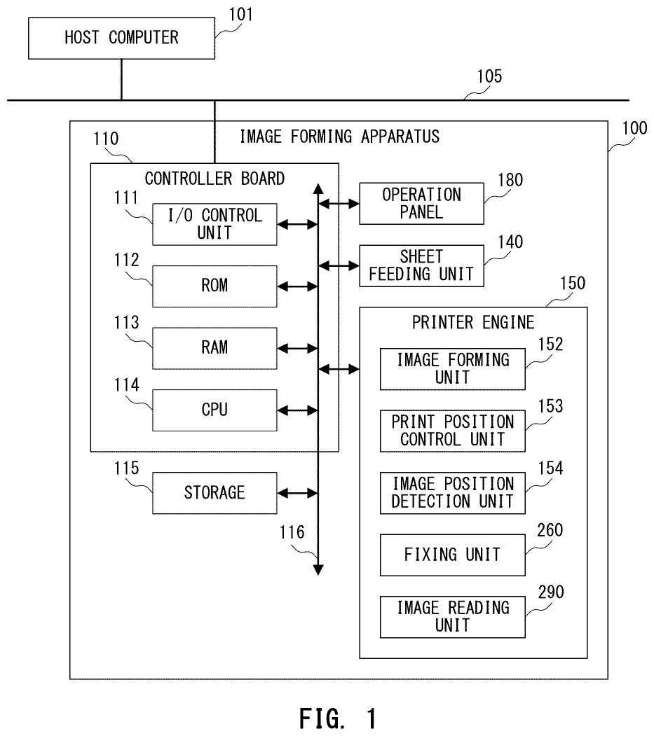

FIG. 1 is a system configuration diagram of an image forming apparatus including a circuit board according to at least one embodiment of the present disclosure. It should be understood that, unless otherwise described, the image forming apparatus 100 may be a system including a plurality of apparatus connected to each other via a network, as long as functions of the image forming apparatus 100 can be implemented.

The image forming apparatus 100 according to the at least one embodiment is connected to a host computer 101 via a network 105 so that communication is allowed therebetween. The network 105 includes a communication line such as a local area network (LAN), a wide area network (WAN), and a public communication line. A plurality of image forming apparatus 100 and a plurality of host computers 101 may be connected to the network 105. The host computer 101 generates a print job based on input information from a user acquired from an input device (not shown), and transmits the generated print job to the image forming apparatus 100 via the network 105.

The image forming apparatus 100 includes a controller board 110, a storage 115, a sheet feeding unit 140, a printer engine 150, and an operation panel 180. The controller board 110, the storage 115, the sheet feeding unit 140, the printer engine 150, and the operation panel 180 are connected to each other via a system bus 116 so that mutual communication is allowed therebetween.

The controller board 110 includes an I/O control unit 111, a read only memory (ROM) 112, a random access memory (RAM) 113, and a central processing unit (CPU) 114. The I/O control unit 111, the ROM 112, the RAM 113, and the CPU 114 are electronic parts mounted on a circuit board. The controller board 110 functions as a main control unit of the image forming apparatus 100, performs various data processing, and controls the operation of the entire image forming apparatus 100. The circuit board is, for example, a printed wiring board having printed wiring formed thereon.

The I/O control unit 111 controls communication to/from an external apparatus such as the host computer 101 via the network 105. The CPU 114 executes a computer program stored in the ROM 112 or the storage 115 to control an operation such as image forming processing to be performed by the image forming apparatus 100. The RAM 113 provides a work area used in a case where the CPU 114 executes processing, and performs storage of temporal data or the like. The storage 115 stores large-capacity data, such as image data or print data, on a temporary or long-term basis. For example, the storage 115 stores image data for generating an image for adjustment for use in adjusting an image forming condition. The storage 115 is a large-capacity storage device, such as a hard disk drive (HDD) or a solid state drive (SSD). Computer programs, such as a startup program, a control program, and an operation system, to be executed by the CPU 114 are stored in the ROM 112 and the storage 115.

The operation panel 180 is a user interface including an input interface and an output interface. The input interface is, for example, key buttons and a touch panel. The output interface is a display, a speaker, and the like. The operation panel 180 receives an instruction or the like through the operation of the user and inputs the received instruction or the like to the CPU 114. The CPU 114 controls the operation of the image forming apparatus 100 in accordance with the instruction. Further, the operation panel 180 displays a state of the image forming apparatus 100 and various setting screens in accordance with the instruction from the CPU 114.

The sheet feeding unit 140 includes a sheet feeding device including one or more sheet feeding stages, and an entire conveying unit for conveying a sheet from one of the sheet feeding stages to a sheet discharging unit. The sheet feeding unit 140 feeds sheets one by one from the sheet feeding stage in accordance with the instruction from the CPU 114.

The printer engine 150 includes an image forming unit 152, a print position control unit 153, an image position detection unit 154, a fixing unit 260, and an image reading unit 290. The image forming unit 152 forms an image (toner image) on the sheet fed by the sheet feeding unit 140. The fixing unit 260 fixes the image (toner image) to the sheet. The image reading unit 290 reads the image for adjustment printed on the sheet. The image position detection unit 154 detects an image position printed on the sheet based on results of reading the image for adjustment by the image reading unit 290. The print position control unit 153 controls the position of the image to be printed on the sheet based on the image position detected by the image position detection unit 154.

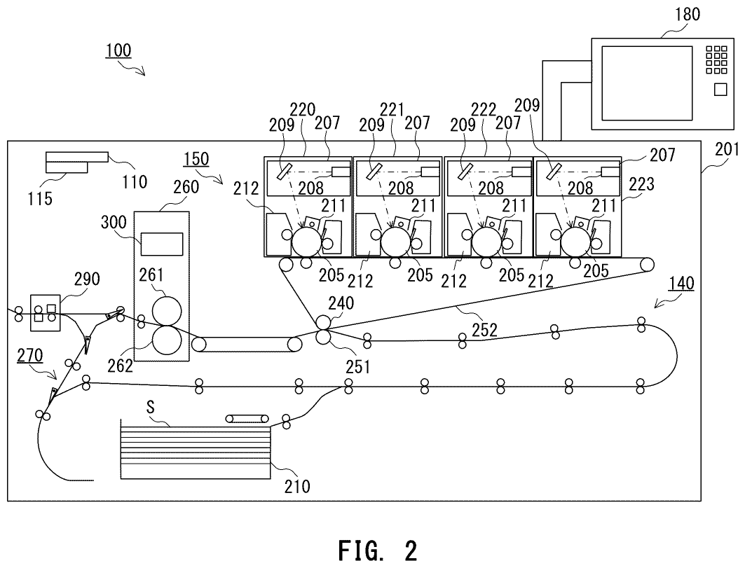

FIG. 2 is a configuration view of the image forming apparatus 100. The image forming apparatus 100 includes the operation panel 180 above a casing 201. Inside of the casing 201, the controller board 110, the storage 115, the sheet feeding unit 140, and the printer engine 150 illustrated in FIG. 1 are provided. The printer engine 150 includes mechanisms forming an engine unit, and an engine control unit for performing control of processing to be performed by each mechanism. The mechanisms forming the engine unit include an optical processing mechanism and a fixing processing mechanism. The optical processing mechanism is used for forming an electrostatic latent image, visualizing the electrostatic latent image, and transferring the visualized image onto a sheet S. The fixing processing mechanism fixes the toner image transferred onto the sheet S.

The image forming unit 152 of the printer engine 150 corresponds to the optical processing mechanism, and includes a Y station 220, an M station 221, a C station 222, a K station 223, an intermediate transfer belt 252, and a secondary transfer outer roller 251. The Y station 220, the M station 221, the C station 222, and the K station 223 have the same configuration, and only differ in colors of images to be formed. The Y station 220 forms a yellow image. The M station 221 forms a magenta image. The C station 222 forms a cyan image. The K station 223 forms a black image. The configuration of the Y station 220 is described here, and a description of the configurations of the M station 221, the C station 222, and the K station 223 is omitted.

The Y station 220 includes a photosensitive drum 205, a charging device 211, an exposing device 207, and a developing device 212. The photosensitive drum 205 is a drum-shaped photosensitive member having a photosensitive layer on its surface. The charging device 211 uniformly charges the surface of the photosensitive drum 205 that rotates about a drum shaft. The exposing device 207 scans the charged surface of the photosensitive drum 205 with laser light photosensitive drum modulated in accordance with the image data.

The exposing device 207 includes a laser driver, a rotary polygon mirror 208, and a reflecting mirror 209. The laser driver controls light emission of a semiconductor laser (not shown) in accordance with the image data acquired from a printer controller 203 (CPU 114). The laser light emitted from the semiconductor laser moves in a main scanning direction in accordance with the rotation of the rotary polygon mirror 208, and is guided by the reflecting mirror 209 to the surface of the photosensitive drum 205. Thus, the laser beam scans the surface of the photosensitive drum 205 in a drum axis direction. The surface of the photosensitive drum 205 is exposed with light so that an electrostatic latent image is formed thereon.

The developing device 212 visualizes the electrostatic latent image with toner of a corresponding color to form a toner image on the surface of the photosensitive drum 205. A yellow toner image is formed on the photosensitive drum 205 of the Y station 220. A magenta toner image is formed on the photosensitive drum 205 of the M station 221. A cyan toner image is formed on the photosensitive drum 205 of the C station 222. A black toner image is formed on the photosensitive drum 205 of the K station 223.

The intermediate transfer belt 252 is looped around rollers such as a secondary transfer inner roller 240, and rotates in the clockwise direction of FIG. 2. The toner images of the respective colors formed on the respective photosensitive drums 205 are transferred in a superimposing manner onto the rotating intermediate transfer belt 252. The toner image is transferred from the photosensitive drum 205 onto the intermediate transfer belt 252 by applying a bias voltage having a polarity reverse to that of the toner image to the intermediate transfer belt 252. In this manner, the intermediate transfer belt 252 bears a full-color toner image. The intermediate transfer belt 252 rotates to convey the borne toner image to a secondary transfer portion formed of the secondary transfer inner roller 240 and the secondary transfer outer roller 251.

The sheet feeding unit 140 corresponds to a feeding mechanism for the sheet S, and includes a storage unit 210k, which is a sheet feeding cassette for storing the sheets S, conveyance paths, and conveying rollers. The sheet feeding unit 140 conveys the sheets S from the storage unit 210 one by one to the secondary transfer portion. The secondary transfer portion nips and conveys the intermediate transfer belt 252 and the sheet S by the secondary transfer inner roller 240 and the secondary transfer outer roller 251. At this time, a bias voltage having a polarity reverse to that of the toner image is applied to the secondary transfer outer roller 251 so that the toner image is transferred from the intermediate transfer belt 252 onto the sheet S.

The sheet S having the toner image transferred thereon is conveyed to the fixing unit 260 corresponding to the fixing processing mechanism. The fixing unit 260 includes a fixing roller 261, a pressure roller 262, and a circuit board 300. The fixing roller 261 incorporates a heat source. The pressure roller 262 is urged to the fixing roller 261 side. The circuit board 300 controls the fixing processing to be performed by the fixing unit 260. The fixing unit 260 nips and conveys the sheet S having the toner image transferred thereon by the fixing roller 261 and the pressure roller 262 so that the toner image is fixed to the sheet S. At this time, the fixing roller 261 heats and melts the toner image, and presses the sheet S between the fixing roller 261 and the pressure roller 262.

In the manner described above, the image is printed on the sheet S. In a case of duplex printing, the sheet S having the image printed on its first surface (front surface) is re-conveyed to the secondary transfer portion via a reverse path 270. Through conveyance to the secondary transfer portion via the reverse path 270, an image forming surface of the sheet S is reversed. On the sheet S whose image forming surface has been reversed, an image is printed on a second surface (back surface) different from the first surface by the secondary transfer portion and the fixing unit 260.

The sheet S having the image printed thereon passes through the image reading unit 290 provided on the downstream side of the fixing unit 260 in a conveying direction of the sheet so as to be discharged to the outside of the image forming apparatus 100. In a case where the image formed on the sheet S is the image for adjustment for adjusting the image forming condition, the image reading unit 290 is used for reading of this image for adjustment.

### Circuit Board

In order to perform the image forming processing as described above, the image forming apparatus 100 incorporates various actuators, such as motors and sensors. The actuators are each connected to a circuit board having electronic parts for control mounted thereon. Each electronic part mounted on the circuit board is connected by a conductive wire. The circuit board according to the present embodiment of the present disclosure is, for example, a printed wiring board using a printed wiring line as the conductive wire.

The electronic part controls the operation of the actuator. A large number of circuit boards are thus provided in the image forming apparatus 100 so as to correspond to the actuators. One or more actuators are controlled by one circuit board. The circuit board is controlled by the CPU 114. The controller board 110 on which the CPU 114 is mounted is also an example of the circuit board.

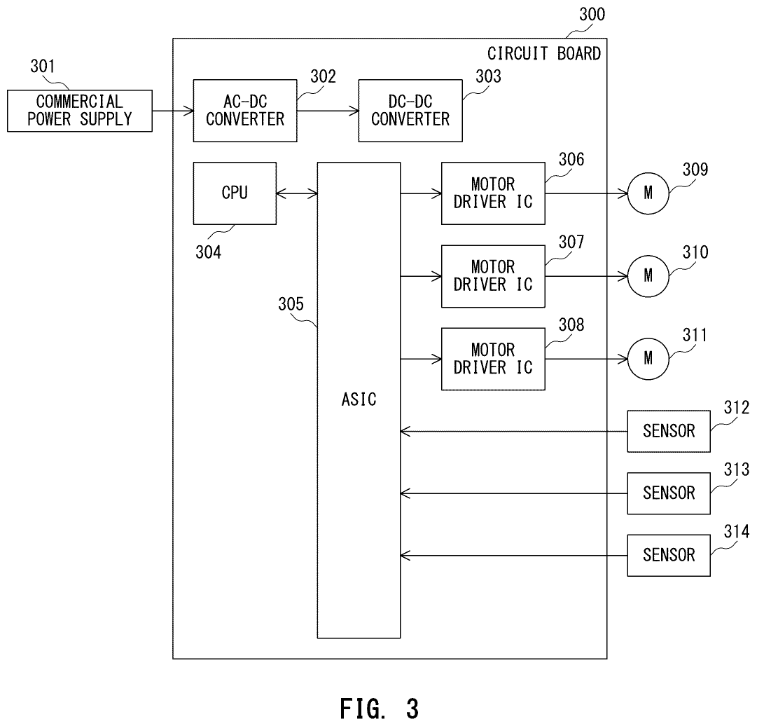

FIG. 3 is a configuration diagram of the circuit board 300 provided in the fixing unit 260. A plurality of motors 309 to 311 in the fixing unit 260 and a plurality of sensors 312 to 314 in the fixing unit 260 are electrically connected to the circuit board 300. The motor 309 is a drive source for driving the fixing roller 261 being a rotary member. The motor 310 is a drive source for urging the pressure roller 262 to the fixing roller 261 side. The motor 311 is a drive source for driving a roller being a rotary member for conveying the sheet S that has been subjected to the fixing processing to the downstream. The sensor 312 is a detector for detecting the sheet S that has been conveyed to the fixing unit 260. The sensor 313 is a temperature detector for detecting the temperature of the fixing roller 261. The sensor 314 is a detector for detecting the sheet S that has been subjected to the fixing processing.

The circuit board 300 implements various functions by a plurality of electronic parts. In the example of FIG. 3, the circuit board 300 includes an AC-DC converter 302 and a DC-DC converter 303. The AC-DC converter 302 is used for generating a predetermined DC voltage from an AC voltage. The DC-DC converter 303 converts a voltage value of the DC voltage. The circuit board 300 further includes a CPU 304, an application specific integrated circuit (ASIC) 305, and motor driver ICs 306 to 308, which are used for control of the actuators. On the circuit board 300, the plurality of integrated circuits (hereinafter referred to as “ICs”) and surrounding electronic parts corresponding to the ICs as described above are mounted as electronic parts.

The AC-DC converter 302 generates, based on AC power supplied from a commercial power supply 301, a power supply voltage which is a DC voltage having a predetermined voltage value. The DC-DC converter 303 generates, based on the power supply voltage supplied from the AC-DC converter 302, a power supply voltage which is a DC voltage having a voltage value different from that of the first power supply voltage. The supply voltage generated by the DC-DC converter 303 is supplied to the CPU 304 and the ASIC 305. The CPU 304 and the ASIC 305 operate with the power supply voltage supplied from the DC-DC converter 303. The power supply voltage output from the AC-DC converter 302 is supplied to the electronic part and motors 309-311 which operate with a voltage value different from the voltage value for operating the CPU 304 or ASIC 305.

The CPU 304 is connected to each of the motor driver ICs 306 to 308 and each of the sensors 312 to 314 via the ASIC 305. The CPU 304 acquires detection results obtained by each of the sensors 312 to 314 to detect the state of the fixing unit 260 from the detection results. The CPU 304 controls each of the motor driver ICs 306 to 308 via the ASIC 305 in accordance with the detected state of the fixing unit 260, to thereby control the drive of each of the motors 309 to 311. As described above, the CPU 304 and the ASIC 305 control the operation of the fixing unit 260.

Since the circuit board 300 is located in the fixing unit 260, it controls the operation of the fixing unit 260. Similarly, the circuit board 300 controls the operations of other circuit boards located in the image forming apparatus 100 and corresponding constituent part. Each of the circuit boards in the image forming apparatus 100 (including the circuit board 300 and other circuit boards) is connected to the controller board 110 so that communication is allowed therebetween. Communication is allowed between circuit boards via the controller board 110. The circuit boards appropriately control the constituent parts in the image forming apparatus 100 while mutually sharing information on the detection results obtained by the sensors and the control states of the motors.

A large number of electronic parts are mounted on the circuit board. In response to such a request, for various reasons such as changes in the distribution of the electronic parts, changes in the environment, and accidents, there is a possibility that a situation in which it becomes difficult to procure some or all of the electronic parts occurs. In order to cope with the situation in which there is an electronic part that is difficult to procure, for each of the electronic parts, an electronic part having the same or similar shape and specification may be prepared as a replacement part. In a case where the original part cannot be procured, the replacement part is mounted on the circuit board so that the manufacture of the circuit board 300 is continued.

However, in the circuit board 300, for example, a particular IC such as an IC for the DC-DC converter 303 and an IC for the motor driver IC 306 (or 307, 308), at the time of use, an inherent peripheral part may be needed. Further, in some cases, there is no replaceable IC because the number of terminals, arrangement, array, or electrical specification of the IC is different. For these cases, in order to cope with the situation in which the procurement of each electronic part becomes difficult, a different electronic part component that can achieve the same function as that of an electronic part component including each IC and its surrounding part is prepared. Those electronic part components are exclusively mounted on the circuit board. With this coping method, a procurable IC is mounted depending on the availability of the mounting part, and hence the manufacture of the circuit board 300 can be continued.

The circuit board 300 of the present embodiment has a configuration capable of coping with the situation in which part procurement is difficult, and is further capable of reducing the area required for mounting without losing the heat dissipation performance of the electronic part. Now, description is given of a specific circuit configuration and wiring (wiring pattern) of the circuit board 300. In the present embodiment, description is given through use of a configuration of a motor driver IC for controlling a two-phase bipolar-drive stepping motor.

### Electronic Part Component

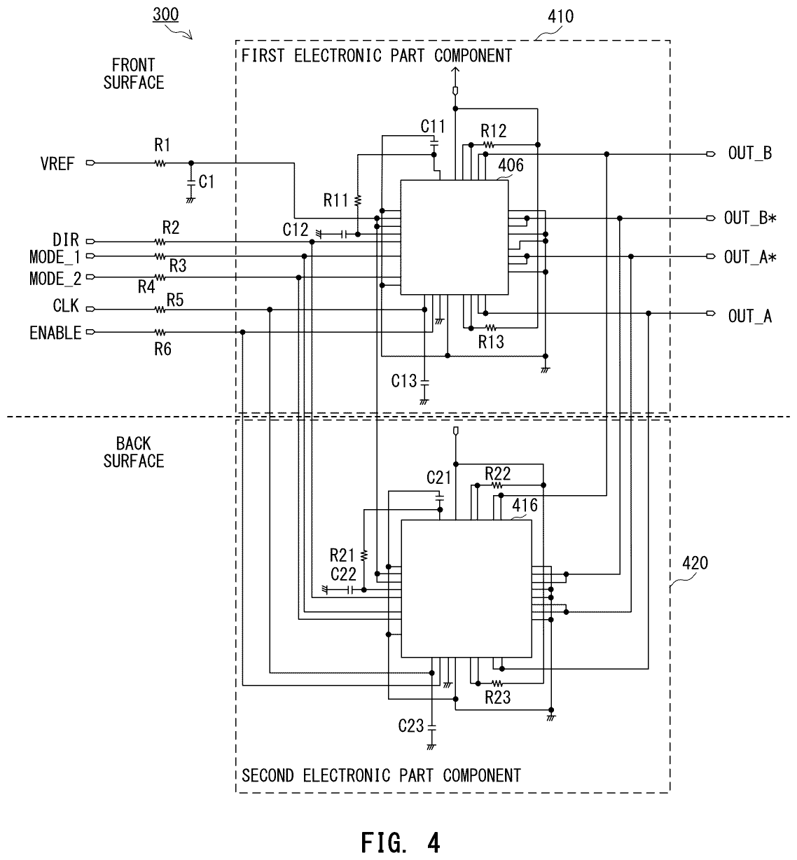

FIG. 4 is an explanatory view of electronic part components each including a motor driver IC and its surrounding part. Those electronic part components are a first electronic part component 410 including a motor driver IC 406, and a second electronic part component 420 including a motor driver IC 416 which is a replacement product of the motor driver IC 406. The first electronic part component 410 and the second electronic part component 420 have similar functions, and are exclusively mounted on the circuit board 300 having the front surface and the back surface. In other words, one of the first electronic part component 410 and the second electronic part component 420 is mounted on the circuit board 300. In this embodiment, in a case where the first electronic part component 410 is to be mounted, it is mounted on the front surface of the circuit board 300. On the other hand, in a case where the second electronic part component 420 is to be mounted, it is mounted on the back surface of the circuit board 300.

The first electronic part component 410 includes resistors R11, R12, and R13 and capacitors C11, C12, and C13 in addition to the motor driver IC 406. The resistors R12 and R13 are detection resistors for detecting currents. The resistor R11 is a resistor for determining a chopping frequency of constant-current pulse width modulation (PWM) control at the time of controlling a motor current. The capacitors C11, C12, and C13 are each provided for noise removal.

Similarly, the second electronic part component 420 includes resistors R21, R22, and R23 and capacitors C21, C22, and C23 in addition to the motor driver IC 416. The resistors R22 and R23 are detection resistors for detecting currents. The resistor R21 is a resistor for determining a chopping frequency of constant-current PWM control at the time of controlling a motor current. The capacitors C21, C22, and C23 are each provided for noise removal.

Control signals branched from the ASIC 305 via damping resistors R1 to R6 are input to the motor driver ICs 406 and 416. The control signals include an ENABLE signal, a CLK signal, a VREF signal, a MODE signal (MODE_1 signal and MODE_2 signal), and a DIR signal. The ENABLE signal is a control signal for enabling the output of the motor driver ICs 406 and 416. The CLK signal is a control signal for controlling a speed of the motor. The VREF signal is a control signal for controlling a value of current flowing through the motor. The MODE signal is a control signal for controlling an excitation pattern of the motor. The DIR signal is a control signal for controlling a rotation direction of the motor. The motor driver ICs 406 and 416 can drive the motor in accordance with an instruction obtained by those control signals. Phase output signals (OUT_A, OUT_A*, OUT_B, and OUT_B*) output from the motor driver ICs 406 and 416 are connected through vias in the shortest distance so as to be input to the motor. The operation of the motor is controlled by those signals input from the motor driver ICs 406 and 416.

As described above, the first electronic part component 410 and the second electronic part component 420 are exclusively mounted on the front surface or the back surface of the circuit board 300. By enabling exclusive mounting on the front surface or the back surface, the distance from terminals of motor driver ICs 406 and 416 to common signal lines such as phase output signals (OUT_A, OUT_A*, OUT_B, OUT_B*) can be minimized.

Further, the circuit board 300 may have a configuration in which exclusive mounting is achieved not in units of electronic part components but in units of ICs. For example, the motor driver IC 406 and the motor driver IC 416 may be exclusively mounted on the front surface or the back surface of the circuit board 300. In this case, for example, the resistors R11, R12, and R13 and the capacitors C11, C12, and C13 may be shared by the motor driver IC 416, and the resistors R21, R22, and R23 and the capacitors C21, C22, and C23 may be omitted.

The motor driver IC406 and the motor driver IC416, which are mounted exclusively, may differ in package size. In the present embodiment, a description is made for a case where the package size of the motor driver IC416 is larger than the package size of the motor driver IC406.

The circuit board 300 of the present embodiment has a multilayer structure. Although the circuit board 300 having a four-layer structure will be explained here, any number of layers may be used as long as they are multilayered. The circuit board 300 having the four-layer structure is a double-sided reflow board, and electronic parts are mounted on one layer (first layer), which is an outermost layer, and the other layer (fourth layer). The motor driver IC406 and the motor driver IC416 are exclusively mounted on the first layer, which is the first surface (front surface), or the fourth layer, which is the second surface (back). The second layer 62 is a power supply layer, and includes a load driving power wiring line, which supplies power to the motor driver ICs 406 and 416, and a logic power wiring line, which supplies a low voltage for the CPU 304 and the ASIC 305 etc. The third layer is a ground (GND) layer, and is connected to ground patterns of the first layer and the fourth layer through vias.

The motor driver ICs 306-308 and ICs of the DC-DC converter 303 are electronic parts which generate heat easily due to the high current flow. Generally, as to the motor driver ICs, operational failures such as thermal shutdowns and failures may occur when the temperature rises to about 150° C. For this reason, when designing motor driver ICs, in the thermal design, an upper temperature limit (100° C. in the present embodiment) with a margin to avoid the risk of operation failure is defined. In the circuit board 300 with ICs mounted exclusively on the front surface or the back surface, a temperature rise of the ICs is designed to be less than or equal to the upper temperature limit specified in the design.

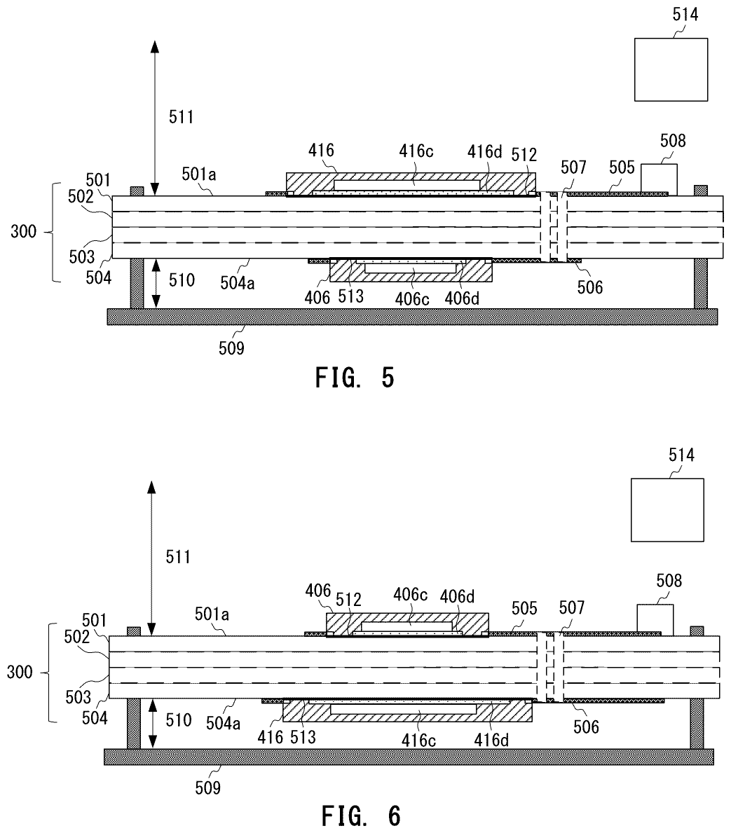

FIG. 5 is a configuration diagram of the circuit board 300 at the time of mounting motor driver ICs 406 and 416. FIG. 5 shows the circuit board 300 viewed from a cross-sectional direction. The circuit board 300 has a four-layer structure including a first layer 501, a second layer 502, a third layer 503, and a fourth layer 504.

On a mounting surface 501a of the first layer 501, a mounting area 512 where the motor driver IC 416 can be mounted is provided. On a mounting surface 504a of the fourth layer 504, a mounting area 513 where the motor driver IC 406 can be mounted is provided. Inside the motor driver IC416, IC chip 416c is provided. Inside the motor driver IC406, IC chip 406c is provided. On a back surface of the motor driver IC 416, a die pad 416d to conduct heat to the circuit board 300. On a back surface of the motor driver IC 406, a die pad 406d to conduct heat to the circuit board 300. The size of the die pad 416d is larger than that of the die pad 406d, as in the package size of each of the motor driver ICs 406 and 416.

At the time of mounting of motor driver IC 406, the die pad 406d is soldered to the mounting area 513. Heat from the IC chip 406c is conducted to the mounting area 513 through the die pad 406d, and is diffused in the circuit board 300. At the time of mounting of motor driver IC 416, the die pad 416d is soldered to the mounting area 512. Heat from the IC chip 416c is conducted to the mounting area 512 through the die pad 416d, and is diffused in the circuit board 300.

A lead of the motor driver IC416 is connected to an output signal line 505. A lead of the motor driver IC406 is connected to an output signal line 506. The output signal line 505 and the output signal line 506 are connected by a via 507 provided through the circuit board 300 from the first layer 501 to the fourth layer 504. The output signal line 505 is connected to a connector 508 provided on the mounting surface 501a.

The circuit board 300 is mounted inside the casing 201 of the image forming apparatus 100 or inside the casing of the fixing unit 260. Here, an example in which the circuit board 300 is mounted inside the casing of the fixing unit 260 will be described. The circuit board 300 is fixedly mounted to a sheet metal 509 so that the fourth layer 504 faces the sheet metal 509 provided inside the casing of the fixing unit 260. The sheet metal 509 is an example of a support member that supports the circuit board 300. In this configuration, the distance (space distance 511) from the mounting surface 501a of the first layer 501 to a surface of the sheet metal of the casing of the fixing unit 260 facing in the normal direction of the mounting surface 501a is larger than the distance (space distance 510) from the mounting surface 504a of the fourth layer 504 to a surface of the sheet metal 509. Thus, the spatial distance 511 of the first layer 501 in a vertical direction is larger than the spatial distance 510 of the fourth layer 504 in the vertical direction. A fan 514 is located to face the first layer 501 of the circuit board 300. The fan 514 cools the entire circuit board 300 by blowing air toward the mounting area 512.

Compared to the spatial distance 511 of the mounting surface 501a of the first layer 501, the spatial distance 510 of the mounting surface 504a of the fourth layer 504 is smaller and has less convection (forced convection in a case where the fan 514 is provided or natural convection in a case where the fan 514 is not provided), resulting in a configuration with lower heat dissipation. Therefore, the motor driver IC 406 mounted on the fourth layer 504 has a higher risk of operational failure, such as thermal shutdown or failure due to the temperature rise, than the motor driver IC 416 mounted on the first layer 501.

In the example shown in FIG. 5, the motor driver IC 416 having a larger package size can be mounted on the first layer 501, and the motor driver IC 406 having a smaller package size can be mounted on the fourth layer 504. The larger the package size, the higher the heat dissipation of an IC. This is because the larger the package size, the higher the amount of heat conducted from the IC to the circuit board via die pads on the back of the IC, and the larger the package size, the greater the amount of heat dissipated by convection on the package surface. Contrary to this, the smaller the package size, the lower the heat dissipation. In other words, in FIG. 5, the motor driver IC 406, which has a small package size and low heat dissipation, is mounted on the fourth layer 504, which is relatively susceptible to the temperature rise.

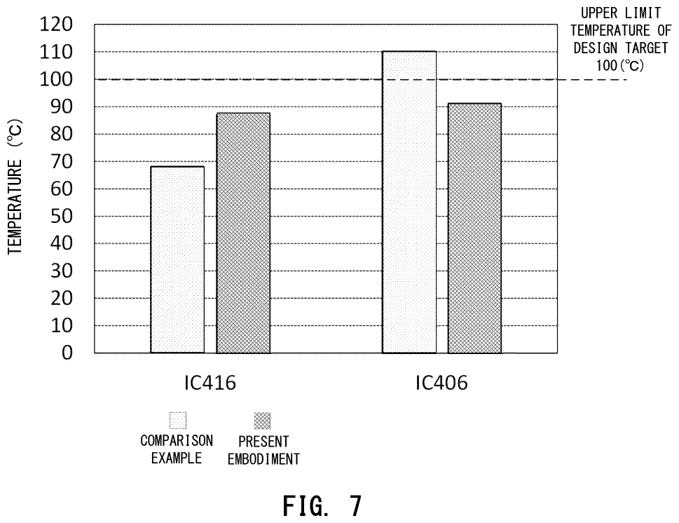

FIG. 6 is a configuration diagram of the circuit board 300 at the time of mounting motor driver ICs 406 and 416 considering the heat dissipation of the ICs. In the example shown in FIG. 6, the motor driver IC 406 having a smaller package size can be mounted on the mounting surface 501a of first layer 501, and the motor driver IC 416 having a larger package size can be mounted on the mounting surface 504a of the fourth layer 504. For this reason, the area of the mounting area 512 of the mounting surface 501a of the first layer 501 is smaller than the area of the mounting area 513 of the mounting surface 504a of the fourth layer 504. As described above, the heat dissipation of the mounting area 512 of the mounting surface 501a is higher than the heat dissipation of the mounting area 513 of the mounting surface 504a due to the difference between the spatial distances 510 and 511. Moreover, the fan 514 further improvers the heat dissipation of the mounting area 512 of the mounting surface 501a.

The mounting area 512 of the mounting surface 501a has a size corresponding to the package size of the motor driver IC 406. The mounting area 513 of the mounting surface 504a has a size corresponding to the package size of the motor driver IC 416. For this reason, the mounting area 512 of the mounting surface 501a is smaller than the mounting area 513 of the mounting surface 504a.

Compared to larger ICs, ICs with smaller package sizes are more prone to temperature rise due to the higher thermal resistance of the heat dissipation path to the circuit board 300 and surrounding atmosphere since the surface areas of the package and die pad are relatively small. In other words, the motor driver IC 406 with a small package size has relatively low heat dissipation, while the motor driver IC 416 with a large package size has relatively high heat dissipation.

In the present embodiment, the motor driver IC 406 with relatively low heat dissipation can be mounted in the mounting area 512 provided on the mounting surface 501a of the first layer 501 with relatively high heat dissipation. The motor driver IC 416 with relatively high heat dissipation can be mounted in the mounting area 513 provided on the mounting surface 504a of the fourth layer 504 with relatively high heat dissipation. Therefore, the temperature rise of the motor driver IC 406 can be suppressed.

FIG. 7 is an explanatory diagram of the temperatures of the motor driver ICs 406 and 416 in a case where the image forming apparatus 100 is continuously operated in the configuration illustrated in FIG. 5 and FIG. 6. The bar graph labeled “Comparison Example” in FIG. 7 represents the temperature increase results with the configuration illustrated in FIG. 5. The bar graph labeled “Present Embodiment” in FIG. 7 represents the temperature increase results with the configuration illustrated in FIG. 6.

In the configuration illustrated in FIG. 5, the temperature of the motor driver IC416 is 68° C. and meets the condition of the upper limit temperature of 100° C. or less, which is the design target temperature. However, the temperature of the motor driver IC406 is 110° C. and exceeds the upper limit temperature of 100° C., which is the upper limit temperature of the design target. Therefore, in a case where the motor driver IC 406 is mounted, operation failures such as thermal shutdown or failure of the motor driver IC 406 may occur.

Although it is possible to suppress the temperature rise by adding one or more fans to the fan 514, increasing the air flow of the fan 514, or increasing the number of layers of the circuit board 300, it would complicate the configuration of an apparatus and increase costs. For this reason, in the present embodiment, the configuration illustrated in FIG. 6 is used. By using the configuration illustrated in FIG. 6, the temperature of mounted ICs can be thermally designed to be below the upper limit temperature of the design target without adding one or more fans to the fan 514 or increasing the number of layers. This reduces the risk of thermal shutdown and failures due to the increased temperature of the IC.

As illustrated in FIG. 6, the motor driver IC 416, which has a large package size and high heat dissipation, is mounted on the fourth layer 504, which has low heat dissipation. Thus, though the temperature of the motor driver IC416 increases from 68° C. to 87° C. (see FIG. 7), the temperature is kept below the upper limit temperature of the design target. The motor driver IC406, which has a small package size and low heat dissipation, is mounted on the first layer 501, which has high heat dissipation. Thus, the temperature of the motor driver IC406 decreases from 110° C. to 91° C. (see FIG. 7), the temperature is kept below the upper limit temperature of the design target.

As described above, for the circuit board 300 to which two or more electronic parts capable of realizing the same function can be mounted exclusively, an electronic part with relatively low heat dissipation is mounted to the mounting area of the mounting surface 501a, which has relatively high heat dissipation, of the circuit board 300. Contrary, an electronic part with relatively high heat dissipation is mounted to the mounting area of the mounting surface 504a, which has relatively low heat dissipation, of the circuit board 300. In the above example, the motor driver IC 406 with a small package size and relatively low heat dissipation is mounted to the mounting area 512 on the mounting surface 501a, which has relatively high heat dissipation, of the first layer 501 of the circuit board 300. The motor driver IC 416 with a large package size and relatively high heat dissipation is mounted to the mounting area 513 on the mounting surface 504a, which has relatively low heat dissipation, of the fourth layer 504 of the circuit board 300. This configuration reduces the risk of operational failures such as thermal shutdowns and failures of the electronic parts with relatively low heat dissipation.

Although FIG. 6 illustrates an example in which the circuit board 300 is arranged horizontally, even in a case where the circuit board 300 is arranged vertically, the electronic parts with relatively low heat dissipation are mounted to areas that has relatively high heat dissipation of the circuit board 300. For example, if the spatial distance 511 of the first layer 501 is larger than the spatial distance 510 of the fourth layer 504 as in FIG. 6, the heat dissipation of the mounting surface 501a of the first layer 501 is higher than that of the mounting surface 504a of the fourth layer 504. In this case, the mounting area of the motor driver IC 406 with low heat dissipation is provided on the mounting surface 501a of the first layer 501. This configuration reduces, even in a case where the circuit board 300 is arranged vertically, the risk of operational failures such as thermal shutdowns and failures of the electronic parts with relatively low heat dissipation.

The above circuit board 300 has a four-layer structure. Similar to this, in other multilayer structure boards such as two-layer or six-layer boards, the electronic parts with relatively low heat dissipation are mounted in the mounting area of the mounting surface with relatively high heat dissipation, and the electronic parts with relatively high heat dissipation are mounted in the mounting area of the mounting surface with relatively low heat dissipation. This produces the same effect as the four-layer circuit board.

In the present embodiment, a description has been given of an example in which semiconductor devices (motor driver ICs 406 and 416) are used as the electronic parts, but the electronic parts are not limited to these ICs. The function of the electronic part is not limited as long as the electronic part is configured to be exclusively mounted to the front surface or the back surface of the circuit board 300. For example, the electronic part may be a switching IC, a field effect transistor (FET), or the like.

Further, a description has been given of an example in which the motor driver IC 416 is used as a replacement part. However, the effect to be obtained by the present embodiment is not limited to such an example. For example, in some cases, the circuit board 300 is designed as a common platform with respect to a plurality of apparatus. At this time, in one model, the first electronic part having a first function is mounted on the first mounting surface, while, in another model, the second electronic part different from the first electronic part and similarly having the first function is mounted on the second surface. In such a case as well, the effect described in the present embodiment can be obtained. As explained above, according to the present disclosure, it is possible to provide a circuit board that can suppress the temperature rise of the electronic parts and also suppress the temperature rise of the electronic parts to suppress occurrence of the operation defects.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-118422, filed Jul. 20, 2023. which is hereby incorporated by reference herein in its entirety.

What is claimed is:

1. A circuit board, comprising:
a first mounting area to which a first electronic part having at least a first function is mountable; and
a second mounting area to which a second electronic part having higher heat dissipation than the first electronic part and at least the first function is mountable,
wherein the first mounting area is provided on a first mounting surface of the circuit board,
wherein the second mounting area is provided on a second mounting surface of the circuit board, the second mounting surface being different from the first mounting surface, and
wherein heat dissipation of the first mounting surface is higher than heat dissipation of the second mounting surface.

2. The circuit board according to claim 1,
wherein the circuit board is mounted to a predetermined apparatus, and
wherein a distance between the first mounting surface and a surface of the apparatus that faces the first mounting area is larger than a distance between the second mounting surface and a surface of the apparatus that faces the second mounting area.

3. The circuit board according to claim 1,
wherein a package size of the first electronic part is smaller than a package size of the second electronic part, and an area of the first mounting area is smaller than an area of the second mounting area.

4. The circuit board according to claim 1,
further comprising a fan configured to ventilate the first mounting surface.

5. The circuit board according to claim 1,
wherein the circuit board has a via connecting an output signal line of the first electronic part to an output signal line of the second electronic part.

6. The circuit board according to claim 5,
wherein a connector to which the output signal line of the first electronic part is connected is provided on the first mounting surface.

7. The circuit board according to claim 1,
wherein the circuit board has a multilayer structure, and the first mounting area is provided on one outermost layer and the second mounting area is provided on the other outermost layer.

8. An image forming apparatus comprising:
the circuit board according to claim 1; and
an image forming part configured to be controlled by one of the first electronic part and the second electronic part, which is mounted on the circuit board.

9. An image forming apparatus comprising:
a circuit board; and
a support member configured to support the circuit board,
wherein the circuit board including:
a first mounting area to which a first electronic part having at least a first function is mountable; and
a second mounting area to which a second electronic part having at least the first function is mountable,
wherein the first mounting area is provided on a first mounting surface of the circuit board,
wherein the second mounting area is provided on a second mounting surface of the circuit board, the second mounting surface being different from the first mounting surface,
wherein the circuit board is supported by the support member so that the second mounting surface faces the support member, and
wherein an area of the first mounting area is smaller than an area of the second mounting area.

10. The image forming apparatus according to claim 9,
wherein a package size of the first electronic part is smaller than a package size of the second electronic part.

11. The image forming apparatus according to claim 9,
further comprising a fan configured to ventilate the first mounting surface.

12. The image forming apparatus according to claim 9,
wherein the image forming apparatus has a via connecting an output signal line of the first electronic part to an output signal line of the second electronic part.

13. The image forming apparatus according to claim 12,
wherein a connector to which the output signal line of the first electronic part is connected is provided on the first mounting surface.

14. The image forming apparatus according to claim 9,
wherein the circuit board has a multilayer structure, and the first mounting area is provided on one outermost layer and the second mounting area is provided on the other outermost layer.
